(19) United States
(12) Patent Application Publication
(10) Pub. No.: US 2025/0089566 A1
(43) Pub. Date: Mar. 13, 2025

(54) HYBRID SOLAR PANEL AND SYSTEM

(71) Applicant: Ami ELAZARI, Holon (IL)

(72) Inventor: Ami ELAZARI, Holon (IL)

(21) Appl. No.: 18/882,919

(22) Filed: Sep. 12, 2024

Related U.S. Application Data
(60) Provisional application No. 63/537,857, filed on Sep. 12, 2023.

(51) Int. Cl. H10N 10/17; H02S 10/10; H02S 40/42; H02S 40/44; H10N 19/00

(52) U.S. Cl. CPC H10N 10/17; H02S 10/10; H02S 40/425; H02S 40/44; H10N 19/00

(57) ABSTRACT

A solar panel system comprises an array of photo-voltaic cells, a cooling arrangement comprising cooling fins, a pipe system for piping coolant around said cooling fins, a coolant storage for storing heated coolant; and thermo-electric diode elements associated with said cooling fins. The thermo-electric diode element generates electricity in the presence of a thermal gradient. During sunlight hours, the coolant is relatively cold and the array is hot. In the absence of sunlight the array is cold, and hot coolant from the storage is piped around the cooling fins. Thus a thermal gradient is present both with and without sunlight and electricity may be continually generated.

### RELATED APPLICATION(S)

This application claims the benefit of priority under 35 USC § 119(e) of U.S. Provisional Patent Application No. 63/537,857 filed on Sep. 12, 2023, the contents of which are incorporated herein by reference in their entirety.

### FIELD AND BACKGROUND OF THE INVENTION

The present invention relates in general to the use of solar energy and more particularly to conversion of solar energy to both electrical and thermal energy using photovoltaic cells in what is known as a PVT multi-solar panel. More particularly but not exclusively the present invention relates to the ability to improve the efficiency of the PVT multi-solar panel.

The conversion of solar energy to thermal or electrical energy may use systems such as photovoltaic arrays, passive absorbers of solar energy, solar furnaces etc., These systems have also been proposed for simultaneously converting solar energy to thermal and electrical energy. However, these systems employ apparatus which are complicated to fabricate, such as sealed solar collector enclosures or plate thermal collectors mounted under the solar cells.

Systems that produce both electrical and solar THERMAL energy simultaneously are referred to as PVT multi-solar systems.

Today, with the massive development of the solar energy market, there is still a need for a simple, reliable and inexpensive system for converting solar energy to thermal and electrical energy.

PV/T (photovoltaic thermal) domestic systems are able to put the heat arising in the system to good use. Various types are available, for example with cover or without, water or air type, etc. A prior proposal by the present applicants uses both water and air for cooling of the PV panels. The created energy may be used for the domestic hot water generation (DHW) and the room heating of a building and also for industrial use and generating electricity from heat using co-generation. The cooling of the PV panels enables the electrical output of the system to be improved. Additionally the panel can be integrated into the facade or the roof of the building.

The prior proposal is a co-generation solar device that makes it possible to convert solar energy into thermal energy and electric energy at the same time using a single integrated system. The system is a solar energy harvesting device, formed by the coupling of:
1. Photovoltaic (PV) modules capable of collecting the visible spectrum of the light; these can be modules based on any commercial technology.
2. A collector, a solar PV/Thermal system that collects the visible & infrared sides of the spectrum, cools the PV cells that generate electricity and makes the heat available for the thermal energy control of the building. The photovoltaic (PV)/Thermal collector can be used to provide façade rooftile panels which in turn provide a building façade that behaves as a living skin surrounding the building, providing water/air flows, capturing heat, storing in an insulated tank and making the heat available for heat control of the living environment, while at the same time the PV cell cooled by the water flow generates electricity for domestic use at greater efficiency since the PV cell is constantly cooled to its temperature of maximal efficiency.
3. Structural building elements such as panels and tiles. The system is designed to be strong enough to fulfill structural roles, being for instance the covering roof or the walls of a building.

In the collectors, a domestic hot water (DHW) flat plate grille panel may be exposed to the highest solar radiation, placed on the back side of PV modules and may be integrated on the free surface of the roof of the buildings. The panels may be fully integrated with any necessary electronic power components.

The system comprises the integration of the PV Panel & cells with a solar cooling device, that makes it possible to exploit solar energy to produce electricity and heat at the same time, using a single device. The water flows in a pipe within the grille on the back of the PV panel to cool the PV cells and thus increase their relative efficiency and at the same time collect the heat for domestic (or for that matter industrial) use.

Additionally, the system provides another advantage. By coupling the two devices, the PV system and the Thermal system, it reduces the operational temperature of the PV cell thus increasing the electrical efficiency and operational life, particularly in relation to the thermal stress of the mechanical structure of the cells. In fact, the system makes possible the circulation of appropriate water and air beyond the PV cells, thus improving the efficiency of the cell and collecting heat just as a traditional solar-thermal element.

Nevertheless, all solar-based systems have one major disadvantage. They do not produce electricity at night.

### SUMMARY OF THE INVENTION

The present embodiments may provide a hot water storage tank that stores hot water from the solar panels during the day. The water may be used as hot water during the day as required but some at least may be expected to be left over. The hot water is then made to flow back through the pipes of the solar-thermal element. The PV cells at night, in the absence of solar radiation, provide a cold surface whereas the pipes carrying the water provide a hot surface. A heat gradient is thus set up which is in the opposite direction to that which exists during the day and thermo-electric diodes set up across the gradient may generate electricity.

The thermo-electric diodes remain in position during the day, when the PV cells are hot and the water pipes are cold. Thus the diodes may produce additional electricity during the day.

That is to say, the invention relates to the use of thermo-electric diodes as an auxiliary electrical generating source associated with the thermal energy part of the system, in which stored heat from operation during sunlight may be used in a reverse flow to set up a thermal gradient in the absence of sunlight and thus generate electricity from the stored energy in the absence of sunlight.

According to an aspect of some embodiments of the present invention there is provided a solar panel system comprising:
an array of photo-voltaic cells;
a cooling arrangement comprising cooling fins associated with the array;
a pipe system for piping coolant around the cooling fins;
a coolant storage for storing heated coolant; and
thermo-electric diode elements associated with the cooling arrangement, the thermo-electric diode elements being configured to generate electricity in the presence of a thermal gradient between the array and the pipe system.

In an embodiment, the thermo-electric elements have a first face and a second face and wherein the first face is towards the coolant system and the second face is towards the array, thereby to provide a thermal gradient between the first face and the second face.

In an embodiment, the array is hot in the presence of sunlight and cold in the absence of sunlight and wherein the pipe system is configured to carry coolant at or below ambient temperature in the presence of sunlight and is switchable to carry heated coolant from the storage in the absence of sunlight, thereby to ensure that the thermal gradient is present both in the presence and absence of sunlight and thereby to generate electricity both in the presence and absence of the sunlight.

Embodiments may comprise a valve arrangement to govern flow of ambient or heated coolant in the pipes and/or a diode arrangement to provide a defined direction to a current generated in the thermo-electric diode elements irrespective of a direction of the thermal gradient.

In embodiments, the thermal electric diode elements comprise a plurality of the elements connected in series over a solar panel.

In embodiments, the coolant is water.

In embodiments, the pipe system comprises copper pipes.

In embodiments, the thermo-electric diode elements are connected between the cooling fins and the pipe system.

More generally, the thermo-electric diode elements are connected between the pipe system and the array.

A thermally conductive glue may be used to connect the cooling fins to the array, for example zinc silicon glue.

According to a further aspect of the present invention there is provided a method of operating a solar panel system of the kind described herein, comprising:
in the presence of sunlight, piping coolant, the coolant at substantially ambient temperature or below ambient temperature, thereby to set up a temperature gradient between the array as a hot side and the pipe system as a cold side, and further to heat the coolant and store the heated coolant in a hot storage; and
in the absence of sunlight, piping the coolant from the hot storage, thereby to set up a second temperature gradient between the array as a cold side and the pipe system as a hot side, thereby to generate electricity from the solar panel system both in the presence and absence of sunlight.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE SEVERAL VIEWS OF THE DRAWING(S)

The patent or application file contains at least one drawing executed in color. Copies of this patent or patent application publication with color drawing(s) will be provided by the Office upon request and payment of the necessary fee.

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a solar panel with thermo-electric diodes according to embodiments of the present invention;

FIG. 2 is a simplified cutaway view of a multisolar PVT TED collector according to embodiments of the present invention;

FIG. 3 is a simplified cutaway view of an integration of a multisolar system according to embodiments of the present invention into a typical private house;

FIG. 4 is a side cutaway view of the system of FIG. 3 within a private house;

FIG. 5 is a schematic view of wiring for the system of FIG. 3 within a private house;

FIG. 6 shows a prototype panel according to embodiments of the present invention under test; and

FIGS. 7, 8 and 9 are graphs of characteristics of the panels under test.

### DESCRIPTION OF SPECIFIC EMBODIMENTS OF THE INVENTION

The present invention, in some embodiments thereof, relates to a solar powered combined hot water and electricity system and, more particularly, but not exclusively, to such a system that is able to produce electricity during the night or at other times when there is no sun.

In embodiments, a solar panel system comprises an array of photo-voltaic cells, a cooling arrangement comprising cooling fins, a pipe system for piping coolant around said cooling fins, a coolant storage for storing heated coolant; and thermo-electric diode elements associated with said cooling fins. The thermo-electric diode element generate electricity in the presence of a thermal gradient. During sunlight hours, the coolant is relatively cold and the array is hot. In the absence of sunlight the array is cold, and hot coolant from the storage is piped around the cooling fins. Thus a thermal gradient is present both with and without sunlight and electricity may be continually generated. The coolant storage may be a hot water tank, which also provides domestic hot water.

The present embodiments may provide a solar powered combined hot water and electricity system that comprises one or more PVT collectors that produce at the same collector simultaneously both electricity from Photovoltaic cells cooled by water cooper plate and cold water circulating in a copper pipe that gets hot while cooling the pv cells and accumulates in a water tank. The tank may for example be a 200 liter DHW tank in which the water is held during the day time at a temperature of 60-70 degrees Celsius. According to the present embodiments ceramic elements of a thermo-electric diode are connected in series between a riser pipe welded to cooper plate that is attached with zinc glue to the back of the PV cells. The thermo-electric diodes assist in cooling the PV cells during the day time as they convert heat into electricity, and at the same time, water in the riser cools the same PV cells and is heated and then kept in the tank. The tank thus stores excess energy from the daytime operation.

At night time the water flow is reversed and hot water from the hot water reservoir tank at 60-70 degrees Celsius is sent into the pipes and heats the back of the of the TEDs (thermo electric diode). At the same time the other sides of the TEDs are exposed to the now cold PV cells. At night time there may easily be a temperature gradient of approx 5 to 10 degrees Celsius. Indeed a more likely difference may be 40-50 degrees and in desert areas it may be even more. Accordingly an electrical current is generated in the TEDs. The TEDs are connected in series and depending on the number of TEDs, the connection and the temperature, the connected TEDs may generate voltages in the range of 36-49 volts DC and 5-10 Amps. Such a DC current may either feed into the grid via a DC-AC inverter or charge a battery storage.

In experiments it was found that the thermal energy produced during the day time and accumulated in a DHW storage tank may be up to four times the amount of energy of the electrical energy produced. Thus, given a standard 500 watt collector that produces electricity with 22% efficiency and has a 60% thermal efficiency, the PVT collector may generate approximately 2500 Watts of electricity and 10,000 Watts of thermal energy every day. Thus a basic private house in Israel using four collectors of 8 sq. m each may allow for 40,000 Watts of thermal energy to be accumulated during the day.

Some or all of the thermal energy may not be used by the family during the day, but if we assume that ⅓ is used. a reverse flow of the thermal hot water accumulated may generate electricity at night. Thus a slow water flow to the PVT collector from the tank, where the TED thermo electric diodes operate at 12-15% efficiency, may generate 10,000 W of electric energy during 5 hours of operation during the night. Accordingly the overall amount of electricity generated is doubled.

Thus the power output of the combined PVT-TED collector device that generates electricity and produces hot water during the day from the sun may be doubled by using a reverse flow of hot water during the night, thus activating the thermo electric diodes used to generate extra electricity during the day to be the primary generators of electricity during the night. In other words the stored water applies heat to one face of the diodes while the PV collectors provide a cold surface for the opposite face during the night due to being exposed to the cold air of the ambient night temperature.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

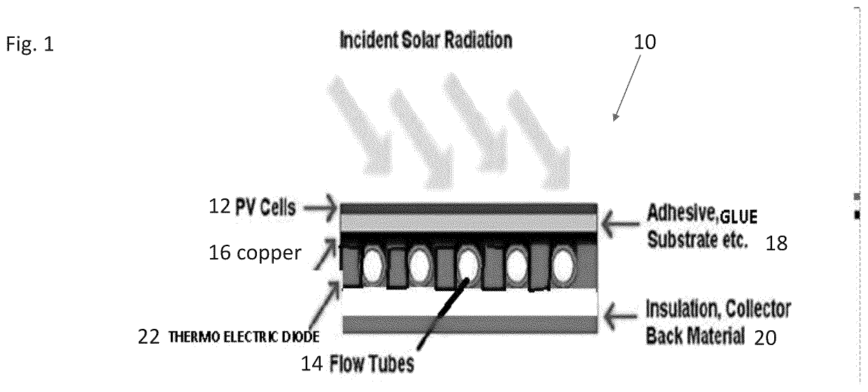

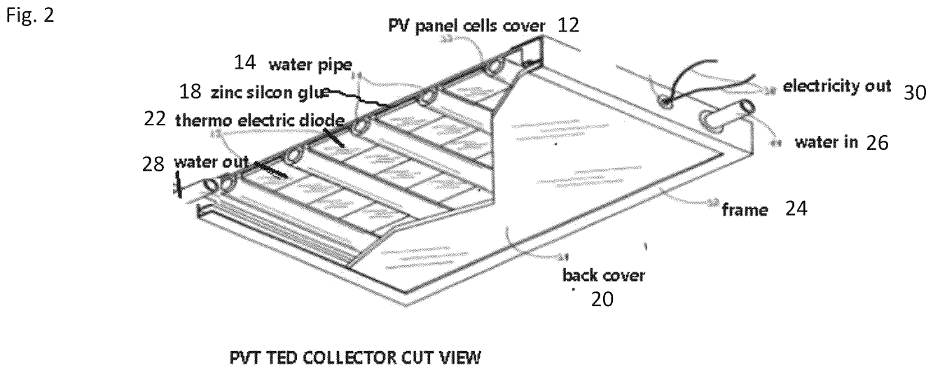

Referring now to FIGS. 1 and 2, PVT TED panel 10 is a combined solar and thermal element that may convert solar energy to thermal and electrical energy within the confines of a flat plate collector. The panel includes a substantially unsealed enclosure within which an array 12 of photovoltaic cells convert solar energy to electrical energy located. The array is located within the enclosure within the panel, and multiple interconnected heat collecting flow tubes 14 or water pipes are welded to a flat plate copper sheet 16 located within the enclosure and disposed on the rear side of the array 12 of photovoltaic cells, so that the plate cools the PV cells and at the same time converts solar energy to thermal energy in fluid disposed within the heat collecting tubes. There is no cover glazing and the photovoltaic (PV) panel may itself serve as a cover for the panel. An adhesive layer 18 attaches the copper sheet 16 to the photovoltaic cells in a way that maintains heat conduction therebetween. For example zinc silicon glue may be used to provide good conduction. The back of the panel may include an insulator or back panel 20. Thermo-electric diodes 22 are connected between the copper sheet 16 and the pipes 14. The panel may be held together by frame 24. Water enters the panel at water inlet 26, flows through pipes 14 and exits at water outlet 28. Electricity generated within the panel is provided through electricity outlet 30.

The system of the present embodiments offers a capacity to collect energy from the sun while it shines, to store it, even for long periods of time, and redistribute it throughout the building according to the needs of the various areas within the building when needed. In hot weather, the panels of the present embodiments, which may be provided on the rooftiles and on the façade, may maintain the right temperature by capturing the excess heat and carrying it away, while circulating fresh air and liquid through the panels around the structure of the building to provide cooling. In embodiments, the panels of the present embodiments may be designed as roof tiles and façade facings.

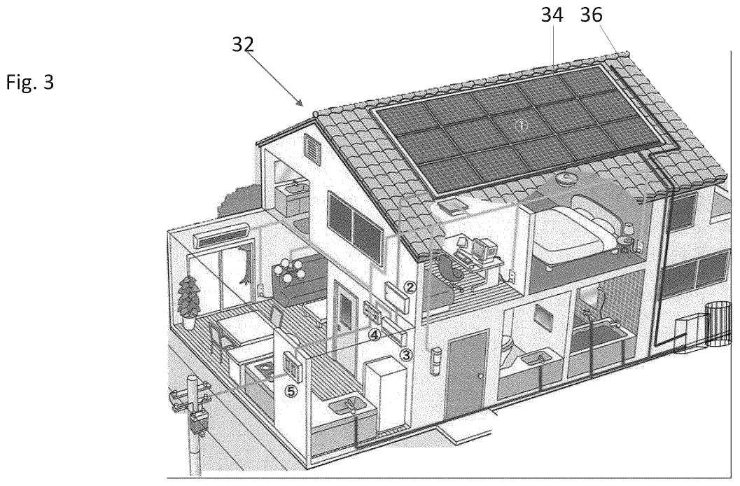

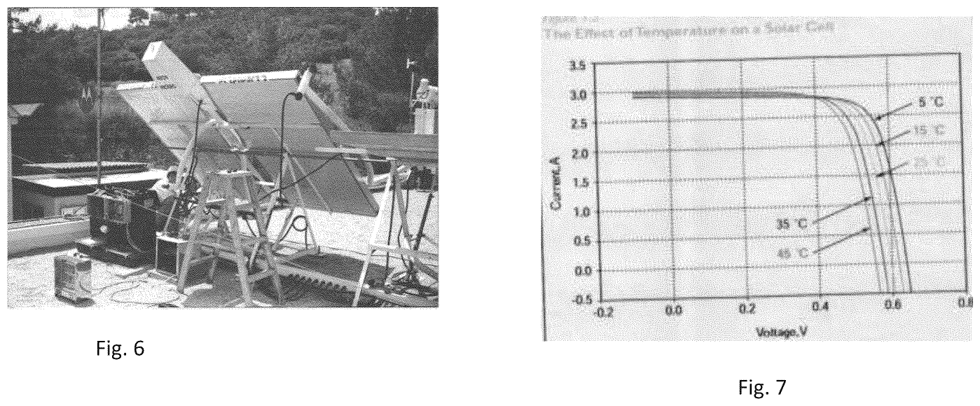

Reference is now made to FIG. 3, which illustrates a typical domestic house 32 to which a solar system of the present embodiments is applied. Panels 34 according to the present embodiments are placed on roof 36. The electricity produced by the PV cells of array 12 (see FIGS. 1 and 2) may be stored (optionally) in a battery bank 118 (See FIG. 5) which may be placed anywhere convenient, for example underground in the basement of the building or under the roof. The DC battery bank may be connected to a DC-AC inverter/charger 128 (See FIG. 5) that is connected to the main building electricity control box. The system may provide all the electricity to the building and sell and buy electricity to and from the electric grid.

As the coolant liquid is heated, the hot coolant may be transferred to a storage tank. The tank may typically be placed underground in the basement of the building, and stone containers may store the heat as the fluid comes in contact with them.

In one embodiment, the tank is a specially insulated reservoir, allowing the storage of heat for long periods. In an embodiment, stone or brick may be used in the tank to collect heat energy from the fluid. The stones or bricks may be immersed in the tank, and may multiply the heat storage potential of the regular DHW water tank. The heat stored in the stone remains for a period of time and can be used to produce hot water after the solar panels have ceased operating. The fluid, or even air that gets into the tank and gets heated by the fluid and the stones may be used for house heating. Thus the heat stored in the tank may be used to heat the interior environment during the cold season. It is noted that in addition, the colder the ambient air, the greater the temperature gradient in the panel so that the same stored fluid can generate more electricity, and thus the house may be fully functional with no need for supplementary heat integration, at least at warmer latitudes.

As mentioned, the cooling fluid may be water and may accordingly provide domestic hot water for the building.

Beyond flat plate hot water panels, double glass PV panels have been developed to serve as window panels or skylights. In double glass PV panels the cooling fluid flows within the pipes, capturing the infrared radiation, but allowing the visible spectrum to flow through, lighting the interior environment. In this way the window can become an active element capable of providing electricity.

The system of the present embodiments may work with circulating air used as the coolant, and may be fitted with automatic valves for interior ventilation with filtered and humidified air using small fans. Thus a source of warm air is integrated in the outer shell of the building and provides heating during the winter at no cost in carbon dioxide or dust emission.

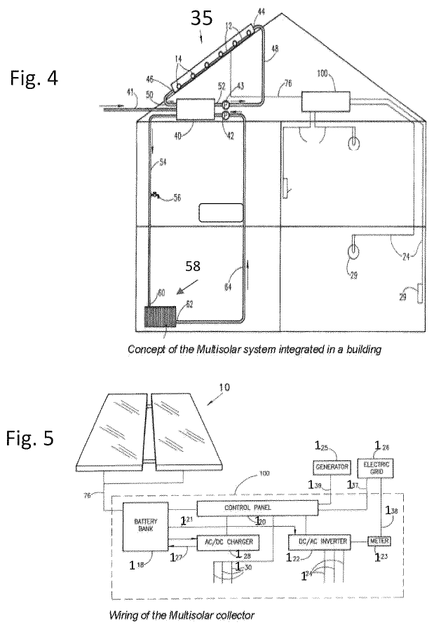

FIGS. 4 and 5 and the related text explain the interaction of the different components and how they may be realized. FIG. 4 shows a diagrammatic sectional illustration of a building incorporating collectors according to the present embodiments for converting solar energy to electrical and thermal energy constructed. FIG. 5 presents a schematic wiring diagram of the electrical system of the Multisolar collector.

In FIG. 4 it can been seen that the hot water storage tank 40, which is typically a commercially available 60-120 liter galvanized iron tank, receives water from the main water supply 41. Water is pumped from the hot water storage tank by an electric water pump 43 through a valve 52 and a pipe 48 to the inlet 44 of interconnected heat collecting tubes 14. The water passes through the network of interconnected heat collecting tubes where it can be heated by thermal energy transferred to the water.

The thermal energy transferred to the water from the heat collecting network can reach about 6500 kcal/day per panel or a total of 13,000 kcal/day for the typical configuration of two panels. Water passes out of the network of interconnected heat collecting tubes through outlet 46 and is returned to the hot water storage tank by a pipe 50.

The circulation of water through the interconnected heat collecting tubes is controlled by a thermostatically operated 12 volt electrical relay, which closes a valve 52 when the water temperature exceeds an adjustably predetermined level. Water flows from the hot water storage tank by gravitation through a pipe 54 to a tap 56 and radiator 58, which may be any of a number of commercially available radiators. The water enters the heat exchanger of radiator 58 through a inlet 60, passes through the heat exchanger where it can transfer thermal energy to the air in the room, exits the heat exchanger through an outlet 62 and is finally returned to the hot water storage tank through pipes 64 and 42. Pumps 42 and 43 typically receive power from one of the DC circuits 130. All these pipes are typically fabricated from a rust resistant material such as anodized aluminum.

The photovoltaic array 12 is electrically connected to an electrical system 100. The electrical system 100 is shown in greater detail in FIG. 5 and typically includes a battery bank 118 connected by cables 76 to the photovoltaic array 12. The battery bank 118 is also connected through a control panel 120 to circuits 130, which provide DC electrical power to electrical appliances 131 and by a cable 121 to a DC/AC inverter 122 as well. Inverter 122 converts the DC current of the battery bank to 220 V or 110 Volt, 50 Hz AC current and supplies it to circuits 124, which provide AC electrical power to electrical appliances 129.

The battery bank 118 typically comprises at least one sealed battery with a capacity of 100 to 5000 Ah at a 24-hour rate. A suitable commercially available battery is the ABSOLYTE II GNB manufactured by SEC Ltd., Inver Bucks SL 09 AG, England. The control panel and the inverter are typically included in a single commercially available power supply unit.

If the voltage level of the battery bank 118 falls below about 14.5 volts the control panel prevents over-discharge of the battery bank by disconnecting it from one or more of the circuits 130 which provide DC power to electrical appliances and/or by disconnecting at least one of the circuits 124 which provide AC electrical power to electrical appliances from the AC/DC inverter. Simultaneously the control panel provides power to the circuits 124, which provide AC current to electric appliances by connecting them to an alternative power source such as the electric power grid 126 or a locally available generator 125.

At the same time the control panel may also connect an AC/DC battery charger 128 via cable 127 to the battery bank 118 to recharge the battery bank 118 and/or to provide power to the circuits 130, which provide DC electrical power to electrical appliances.

If the voltage level of battery bank 118 falls below 10.4 volts, control panel 120 disconnects the battery bank and the DC/AC inverter from all the circuits, whether they provide AC or DC electrical power to any electrical appliances, and connects all circuits 124, which provide AC electrical power to electrical appliances, to the electric power grid via a cable 137 or a generator 125 via another cable 139.

The control panel 120 of the electrical system typically comprises voltage regulators which maintain line voltage in AC and DC circuits, relays to connect the various components of the electrical system, a battery bank voltage level detector, and circuits 138 to return power

| | |
|---|---|
| 1.27 m*2.17 m (2.77 Sq. meter) | Length/Width (m) |
| 3,300 kcal/m2 per day under Israeli | Thermal output |
| climatic conditions | |
| 0.20-0.22 kW/m2 per day under | Electrical output |
| Israeli climatic conditions | |
| 55 degrees Celsius | Maximum output temp water (under |
| | normal operating conditions) |

generated by the photovoltaic array 12 to the electric power grid when the battery bank 118 is fully charged.

The return power path passes through the battery bank, the DC/AC inverter, and metering apparatus 123, which records the amount of power returned to the electric power grid 126.

The voltage regulators may provide 110/120 or 220/240V AC power at ±1% RMS and 12 or 24 volts DC power at +1% of the rated voltage. The voltage regulators, the battery bank voltage level detector and the metering apparatus are preferably commercially available units.

TABLE 1
Panel Characteristics

| | |
|---|---|
| 70% hot water (70% if the air is not used) | Thermal Efficiency |
| 22% | Electrical efficiency |
| Overall efficiency is 92% | Additional comments |

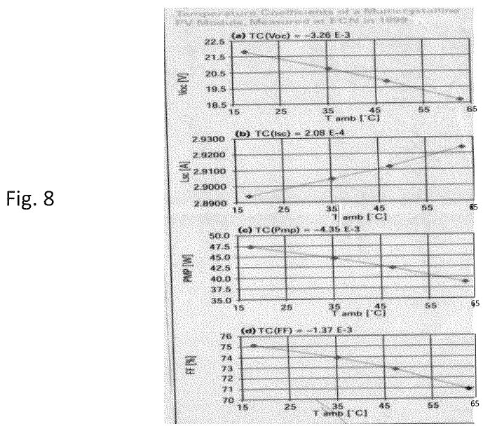

The collector panel of the present embodiments may be a fluid-transfer, thermal energy capture concept, made of panels with a double air/liquid reversible circuit used for heat/cold transfer. It allows the walls, windows and roof of buildings to capture thermal energy and assist in maintaining the interior environment of the building at a temperature which is comfortable for humans to live and work. The Multisolar collector was tested in Chromagen, Israel-See FIG. 6.

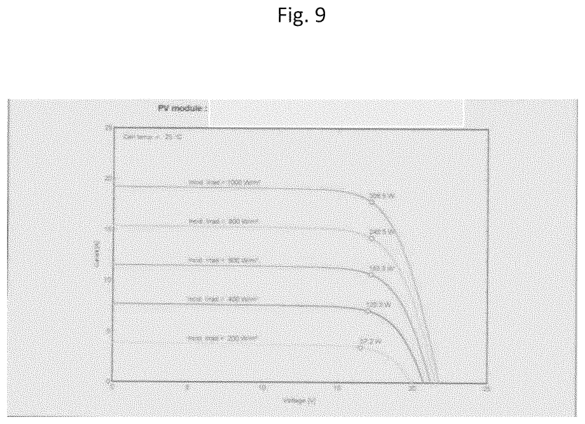

Temperature effect on the modules can be critical in some areas. In full sun, the module temperature can increase to 70° C. Normally, a quality module has a temperature coefficient of about −2.5V/° C./cell. At 70° C. a 36 cell module should be able to charge the battery sufficiently. Because a protection diode is connected in series with the module in most systems, the voltage drop across this diode should also be taken into account. The I/V curve of a single cell at different temperatures, shows how the output voltage declines with increase in temperature. As shown in FIG. 7, the relationship is almost linear.

The temperature coefficient increases with a decrease in module quality. At 25° C. (STC) a 23 cell module based on a cells from FIG. 8, would have an open circuit voltage of 21.96V at 70° C. this will be 17.91V. {(70-25)*2.5 mV/° C./cell*36 cells=4.05V lower}. In India, the temperature coefficient of some (locally manufactured) modules was so high, that it was not possible in some situations to charge the battery up to HVDF point. When the open circuit voltage Voc of a single cell drops to 0.4V at 70° C., the total module will give only 14.4V. When the blocking diode is also considered, the actual maximum charging voltage is 14.0V. Because the battery is never fully charged, this contributes to a decrease in the lifetime of the battery. To illustrate the temperature effect on the module, FIG. 8 shows the temperature coefficients of a 36 cell module in percentages.

In FIG. 8, the temperature coefficient of the open circuit is 3.26 percent for every 10° C. FIG. 9 shows, the voltage reduces with temperature increase, while the current increases slightly. When the product of voltage and current is examined, the voltage coefficient wins. Hence, the module power in the maximum power point decreases by 4.35 percent/10° C.

Using the above-discussed construction, including thermo-electric diodes and a hot-water storage tank, electricity generation may continue during the night.

As explained, a solar-powered combined hot water and electricity system may comprise one or more PVT collectors that produce at the same collector simultaneously both electricity from Photovoltaic cells cooled by water cooper plate and also provide heating of cold water circulating in a copper pipe that gets hot while cooling the pv cells. The heated water may accumulate in a water tank. The tank may for example be a 200 liter DHW tank in which the water is held during the day time at a temperature of 60-70 degrees Celsius and may additionally include stone elements or like features for retention of heat.

Referring again to FIGS. 1 and 2, ceramic elements of a thermo-electric diode are connected in series between a riser pipe welded to cooper plate that is attached with zinc glue 18 to the back of the PV cells. The thermo-electric diodes 22 assist in cooling the PV cells during the day time as they convert heat into electricity, and at the same time, water in the riser cools the same PV cells 22 and is heated and then kept in the tank. The tank thus stores excess energy from the daytime operation.

At night time the water flow is reversed and hot water from the hot water reservoir tank at 60-70 degrees Celsius is sent into the pipes 14 and heats the back of the TEDs (thermo electric diode) 22. At the same time the other sides of the TEDs 22 are exposed to the now cold PV cells 12. At night time there may easily be a temperature gradient of approx. 5 to 10 degrees Celsius. Indeed a more likely difference may be 40-50 degrees and in desert areas it may be even more. Accordingly, an electrical current is generated in the TEDs 22. The TEDs 22 are connected in series and depending on the number of TEDs, the connection and the temperature, may generate voltages in the range of 36-49 volts DC and 5-10 Amps. Such a DC current may either feed into the grid via a DC-AC inverter or charge a battery storage.

In experiments it was found that the thermal energy produced during the day time and accumulated in a DHW storage tank may be up to four times the amount of energy of the electrical energy produced. Thus, given a standard 500 watt collector that produces electricity with 22% efficiency and has a 60% thermal efficiency, the PVT collector may generate approximately 2500 Watts of electricity and 10,000 Watts of thermal energy every day. Thus a basic private house in Israel using four collectors of 8 sq. m each may allow for 40,000 Watts of thermal energy to be accumulated during the day. The figures may vary for other countries based on the specific local climate.

Some or all of the thermal energy may not be used by the family during the day, but if we assume that ⅓ is used, a reverse flow of the thermal hot water accumulated may generate electricity at night. Thus a slow water flow to the PVT collector from the tank, where the TED thermo electric diodes operate at 12-15% efficiency, may generate 10,000 W of electric energy during 5 hours of operation during the night. Accordingly the overall amount of electricity generated is doubled.

Thus the power output of the combined PVT-TED collector device that generates electricity and produces hot water during the day from the sun may be doubled by using a reverse flow of hot water during the night, thus activating the thermo electric diodes used to generate extra electricity during the day to be the primary generators of electricity during the night. In other words the stored water applies heat to one face of the diodes while the PV collectors provide a cold surface for the opposite face during the night due to being exposed to the cold air of the ambient night temperature.

Herein, the terms “comprises”, “comprising”, “includes”, “including”, “having” and their conjugates mean “including but not limited to”.

The term “consisting of” means “including and limited to”.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment and the present description is to be construed as if such embodiments are explicitly set forth herein. Conversely, various features of the invention, which are, for brevity, described in the context of a single embodiment, may also be provided separately or in any suitable subcombination or may be suitable as a modification for any other described embodiment of the invention and the present description is to be construed as if such separate embodiments, subcombinations and modified embodiments are explicitly set forth herein. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. A solar panel system for generating electricity, comprising:
an array of photo-voltaic cells;
a cooling arrangement comprising cooling fins associated with said array;
a pipe system configured to pipe coolant around said cooling fins;
a coolant storage for storing heated coolant fluid; and
thermo-electric diode elements associated with said cooling arrangement, said thermo-electric diode elements being configured to generate electricity in the presence of a thermal gradient between said array and said pipe system, said thermal gradient having a hot side and a cold side, said hot side being provided by solar energy striking said photovoltaic cells when sunshine is available and being provided by said coolant being circulated from said coolant storage by said pipe system around said cooling fins in the absence of sunshine.

2. The solar panel system of claim 1, wherein said thermo-electric elements have a first face and a second face and wherein said first face is towards said coolant system and said second face is towards said array, thereby to provide a thermal gradient between said first face and said second face.

3. The solar panel system of claim 1, wherein said array is hot in the presence of said sunshine and cold in the absence of said sunshine and wherein said pipe system is configured to carry coolant at or below ambient temperature in the presence of said sunshine and is switchable to carry heated coolant from said storage in the absence of said sunshine, thereby to ensure that said thermal gradient is present both in the presence and absence of sunshine and thereby to generate electricity both in the presence and absence of said sunshine.

4. The solar panel system of claim 1, comprising a valve arrangement to govern flow of ambient or heated coolant in said pipes and/or a diode arrangement to provide a defined direction to a current generated in said thermo-electric diode elements irrespective of a direction of said thermal gradient.

5. The solar panel system of claim 1, wherein said thermal electric diode elements comprise a plurality of said elements connected in series over a solar panel.

6. The solar panel system of claim 1, wherein said coolant is water.

7. The solar panel system of claim 1, wherein said pipe system comprises copper pipes.

8. The solar panel system of claim 1, wherein said thermo-electric diode elements are connected between said cooling fins and said pipe system.

9. The solar panel system of claim 1, wherein said cooling fins comprise a copper sheet.

10. The solar panel system of claim 9, wherein said copper sheet is attached to said array of photovoltaic cells via zinc silicon glue.

11. The solar panel system of claim 1, wherein said coolant storage comprises stones or bricks as additional heat storage structures.

12. A method of operating a solar panel system according to claim 1 comprising:
in the presence of sunshine, piping coolant, the coolant at substantially ambient temperature or below ambient temperature, thereby to set up a temperature gradient between said array as a hot side and said pipe system as a cold side, and further to heat said coolant and store said heated coolant in a hot storage; and
in the absence of sunshine, piping said coolant from said hot storage, thereby to set up a second temperature gradient between said array as a cold side and said pipe system as a hot side, thereby to generate electricity from said solar panel system both in the presence and absence of sunshine.
